(19) United States
(12) Patent Application Publication
(10) Pub. No.: US 2025/0393195 A1
(43) Pub. Date: Dec. 25, 2025

(54) MEMORY DEVICES AND FABRICATING METHODS THEREOF

(71) Applicant: YANGTZE MEMORY TECHNOLOGIES CO., LTD., Wuhan (CN)

(72) Inventors: Fan Gong, Wuhan (CN); Bin Yuan, Wuhan (CN); Bo Xu, Wuhan (CN); Jingyu Zhai, Wuhan (CN); Zhenyu Miao, Wuhan (CN); Wei Xu, Wuhan (CN); Zongliang Huo, Wuhan (CN)

(21) Appl. No.: 18/790,623

(22) Filed: Jul. 31, 2024

Related U.S. Application Data
(63) Continuation of application No. PCT/CN2024/100950, filed on Jun. 24, 2024.

(51) Int. Cl. H10B 12/00

(52) U.S. Cl. CPC H10B 12/33; H10B 12/036; H10B 12/05

(57) ABSTRACT

Memory devices and fabricating methods thereof are provided. A disclosed memory device comprises an array of transistors, an array of capacitors, and an array of contact structures connected between the array of transistors and the array of capacitors. Each transistor comprises a semiconductor body extending along a vertical direction. Gate structures of adjacent transistors are laterally separated from each other by an insulating layer having a first material. Each contact structure is aligned with a corresponding semiconductor body in the vertical direction. Adjacent contact structures are laterally separated from each other by a protection layer having a second material different from the first material. Each capacitor is in contact with a corresponding one of the array of contact structures.

### CROSS-REFERENCE TO RELATED APPLICATIONS

This application is a continuation of International Application No. PCT/CN2024/100950, filed on Jun. 24, 2024, which is hereby incorporated by reference in its entirety.

### TECHNICAL FIELD

The present disclosure generally relates to the field of semiconductor technology, and more particularly, to memory devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In some aspects of the present disclosure, a memory device comprises: an array of transistors each comprising a semiconductor body extending along a vertical direction, wherein gate structures of adjacent transistors are laterally separated from each other by an insulating layer having a first material; an array of contact structures each aligned with a corresponding semiconductor body in the vertical direction, wherein adjacent contact structures are laterally separated from each other by a protection layer having a second material different from the first material; and an array of capacitors each in contact with a corresponding one of the array of contact structures.

In some implementations, each contact structure comprises: a silicide layer in contact with a doped end of the corresponding semiconductor body; and a conductive layer in contact with a first electrode of a corresponding one of the array of capacitors.

In some implementations, a vertical distance between the silicide layer of each contact structure and the gate structure of the corresponding transistor is in a range from about 40 nm to about 70 nm.

In some implementations, the first material comprises silicon oxide; and the second material comprises silicon nitride.

In some implementations, the insulating layer extends in between the silicide layer and the protection layer; and a first lateral dimension of the silicide layer is less than a second lateral dimension of the conductive layer.

In some implementations, a sidewall of the silicide layer of each contact structure is vertically aligned with a sidewall of the corresponding semiconductor body.

In some implementations, each semiconductor body has a cylinder shape without an enlarged end adjacent to the silicide layer.

Another aspect of the present disclosure provides a memory device, comprising: an array of transistors each comprising a semiconductor body extending along a vertical direction and a gate structure at a lateral side of the semiconductor body; an array of contact structures each aligned with a corresponding one of the semiconductor bodies of the array of transistors in the vertical direction, wherein vertical distances between the contact structures and the gate structures are in a range from about 40 nm to about 70 nm; a protection layer located between adjacent contact structures to separate the array of contact structures from each other; and an array of capacitors each in contact with a corresponding one of the array of contact structures.

In some implementations, the gate structures of adjacent transistors are laterally separated from each other by an insulating layer having a first material different from a second material of the protection layer.

Another aspect of the present disclosure provides a method of forming a memory device, comprising: forming an array of transistors each comprising a semiconductor body extending along a vertical direction, wherein gate structures of adjacent transistors are laterally separated from each other by an insulating layer having a first material; forming an array of contact structures each aligned with a corresponding semiconductor body in the vertical direction, wherein adjacent contact structures are laterally separated from each other by a protection layer having a second material different from the first material; and forming an array of capacitors each in contact with a corresponding one of the array of contact structures.

In some implementations, forming the array of contact structures comprises: forming the protection layer covering ends of the semiconductor bodies and between ends of the semiconductor bodies of the array of transistors; removing portions of the protection layer to expose the ends of the semiconductor bodies; and removing portions of the ends of the semiconductor bodies to form recesses.

In some implementations, the method further comprises: before forming the protection layer, removing portions of the insulating layer to expose sidewalls of the ends of the semiconductor bodies; and forming a spacer layer covering top surfaces and the sidewalls of the ends of the semiconductor bodies.

In some implementations, forming the array of contact structures further comprises: doping the ends of the semiconductor bodies from the recesses; forming a silicide layer on doped ends of the semiconductor bodies; and forming a conductive layer on the silicide layer.

In some implementations, forming the silicide layer comprises: depositing a metal material in the recesses; performing a first rapid heat annealing process to diffuse the metal material into the doped ends of the semiconductor bodies; removing exceeded metal material; and performing a second rapid heat annealing process to form the silicide layer.

In some implementations, forming the array of capacitors comprises: forming first electrodes of the array of capacitors, wherein each first electrode is in contact with the conductive layer of a corresponding one of the array of contact structures; forming a high-k layer covering the first electrodes; forming second electrodes of the array of capacitors on the high-k layer; and forming a common electrode in contact with the second electrodes.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a memory device including an array of memory cells according to some implementations of the present disclosure.

FIG. 2A illustrates a schematic side view of a cross-section of a memory device, according to some implementations of the present disclosure.

FIG. 2B illustrates a schematic side view of a cross-section of a memory device, according to some implementations of the present disclosure.

FIG. 3 illustrates a block diagram of a system having a memory device, according to some implementations of the present disclosure.

FIG. 4 illustrates a flowchart of a fabricating method for forming a memory device, according to some implementations of the present disclosure.

FIGS. 5A-5J each illustrates schematic views of the memory device at a certain fabricating stage of the method shown in FIG. 4, according to various implementations of the present disclosure.

FIG. 6 illustrates a flowchart of a fabricating method for forming a memory device, according to some implementations of the present disclosure.

FIGS. 7A-7J each illustrates schematic views of the memory device at a certain fabricating stage of the method shown in FIG. 6, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as dynamic radon access memory (DRAM). In a one-transistor-one-capacitor (1T1C) DRAM structure or in a one-transistor-N-capacitor (1TNC) DRAM structure, the data is stored in the capacitors. Generally, the source terminal of each transistor is connected to a corresponding capacitor through a source node contact (SNC) structure normally including a silicide layer in contact with the source terminal and a conductive layer in contact with the capacitor.

Several key factors of the fabricating process of forming the SNC structures significantly impact the stability and performance of the SNC structures. First, the quality of the silicide interface is crucial as it directly affects the resistance and electron mobility of the SNC structures. Poor interface quality can lead to high resistance and instability. To prevent oxidation or other chemical attacks, the silicide interface is required to be appropriately protected, such as by using passivation layers or other protective materials. Second, during the manufacturing process, the silicon material of the source terminals of transistors may suffer physical damage, such as scratching damage and etching damage, which can affect the electrical performance and reliability of the device. Mitigating or repairing these damages, often through annealing or other repair techniques, is required. Third, the overlap region between the N+ doped area and the silicide must remain consistent and stable to ensure good ohmic contact, necessitating precise control of the doping and silicide formation process parameters. Fourth, missing word lines (WL) or isolation oxides (TISO) can lead to device malfunction or performance degradation, making accurate detection methods crucial during the manufacturing process to identify and repair these defects, ensuring the integrity of the device.

To address one or more of the aforementioned issues, the present disclosure introduces a novel DRAM architecture including self-aligned SNC structures. Consistent with the scope of the present disclosure, according to some implementations of the present disclosure, the disclosed DRAM architecture includes vertical transistors, vertical capacitors, and SNC structure connected in between. Each vertical transistor includes a semiconductor body extending in a vertical direction and a gate structure laterally beside the semiconductor body. In some implementations, the word lines and bit lines connected to the vertical transistors are arranged along a first lateral direction and a second lateral direction, respectively. Each vertical capacitor includes vertically extended first electrode, second electrode, and capacitor dielectric between the first and second electrodes. Each SNC structure is aligned with the semiconductor body of a corresponding transistor in a vertical direction. Adjacent SNC structures are laterally separated from each other by a protection layer.

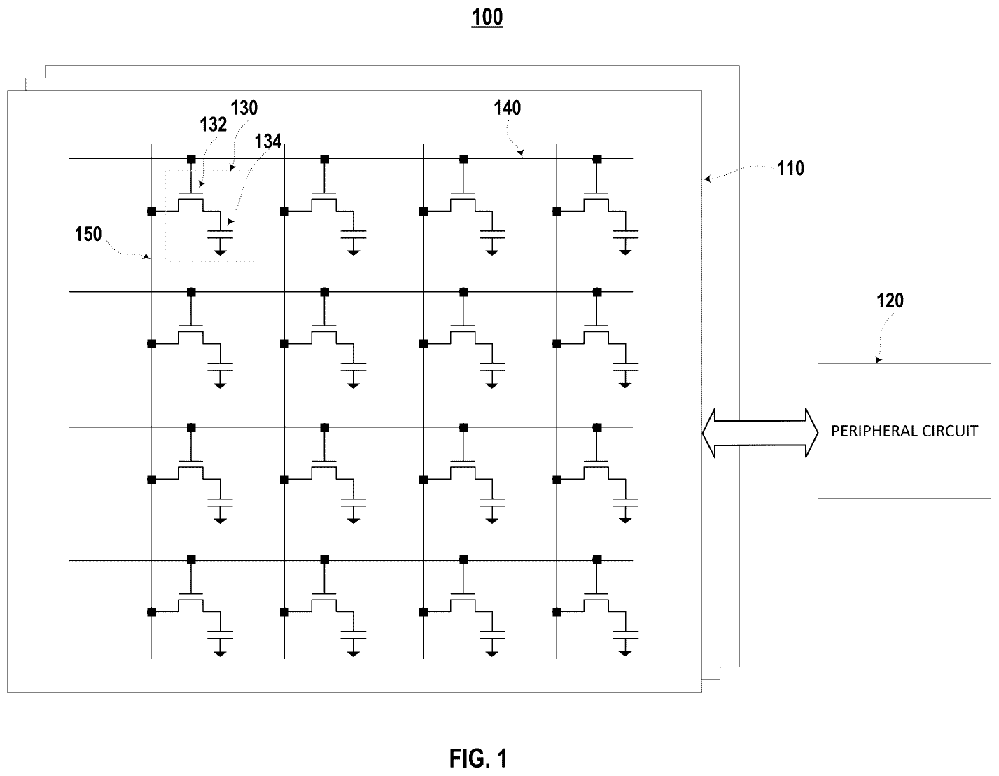

FIG. 1 illustrates a schematic diagram of a memory device 100 including peripheral circuits and an array of memory cells each having a vertical transistor, according to some aspects of the present disclosure. Memory device 100 can include a memory cell array 110 and peripheral circuits 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell. As shown in FIG. 1, memory cells 130 can be arranged in a two-dimensional (2D) array having rows and columns. Peripheral circuits 120 can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits 120 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Memory device 100 can include word lines 140 coupling peripheral circuits 120 and memory cell array 110 for controlling the switch of vertical transistors 132 in memory cells 130 located in a row, as well as bit lines 150 coupling peripheral circuits 120 and memory cell array 110 for sending data to and/or receiving data from memory cells 130 located in a column. That is, each word line 140 is coupled to a respective row of memory cells 130, and each bit line 150 is coupled to a respective column of memory cells 130.

Consistent with the scope of the present disclosure, vertical transistors 132, such as vertical metal-oxide-semiconductor field-effect transistors (MOSFETs), can replace the conventional planar transistors as the pass transistors of memory cells 130 to reduce the area occupied by the pass transistors, the coupling capacitance, as well as the interconnect routing complexity, as described below in detail. As shown in FIG. 1, in some implementations, different from planar transistors in which the active regions are formed in the substrates, vertical transistor 132 includes a semiconductor body extending vertically (in the z-direction) above the substrate (not shown). That is, the semiconductor body can extend above the top surface of the substrate to expose not only the top surface of the semiconductor body, but also one or more side surfaces thereof. As shown in FIG. 1, for example, the semiconductor body can have a cuboid shape to expose four sides thereof. It is understood that the semiconductor body may have any suitable shape, such as a polyhedron shape or a cylinder shape. That is, the cross-section of the semiconductor body in the plan view (e.g., in the x-y plane) can have a square shape, a rectangular shape (or a trapezoidal shape), a circular (or an oval shape), or any other suitable shapes. It is understood that consistent with the scope of the present disclosure, for semiconductor bodies that have a circular or oval shape of their cross-sections in the plan view, the semiconductor bodies may still be considered to have multiple sides, such that the gate structures are coupled with more than one side of the semiconductor bodies.

In some implementations, the semiconductor bodies can be formed from the substrate (e.g., by etching or epitaxy) and thus, have the same semiconductor material (e.g., silicon crystalline silicon) as the substrate (e.g., a silicon substrate). In some implementations, the semiconductor bodies can include metal oxide and semiconductor materials, such as low-temperature polysilicon (LTPS) and indium gallium zinc oxide. Specifically, semiconductor bodies can include one or more of indium gallium zinc oxide (InₓGa_{y}Zn₂O), indium gallium silicon oxide (InₓGa_{y}Si_{z}O), indium stannum zinc oxide (InₓSn_{y}Zn₂O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn₂O), stannum oxide (SnₓO), hafnium indium zinc oxide (HfₓIn_{y}Zn₂O), gallium zinc stannum oxide (GaₓZn_{y}Sn₂O), aluminum zinc stannum oxide (AlₓZn_{y}Sn_{z}O), ytterbium gallium zinc oxide (YbₓGa_{y}Zn₂O), indium gallium oxide (InₓGa_{y}O), etc.

As shown in FIG. 1, vertical transistor 132 can also include a gate structure coupled with one or more lateral sides of semiconductor body. In other words, the active region of vertical transistor 132, i.e., the semiconductor body, can be at least partially surrounded by the gate structure. The ate structure can include a gate dielectric over one or more sides of the semiconductor body, e.g., coupled with four side surfaces of the semiconductor body as shown in FIG. 1. The gate structure can also include a gate electrode over and coupled with gate dielectric. The gate dielectric can include any suitable dielectric materials, such as silicon oxide, silicon nitride, silicon oxynitride, or high-k dielectrics. Gate electrodes can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

As shown in FIG. 1, vertical transistor 132 can further include a pair of a source and a drain (S/D, dope regions, a.k.a., source electrode and drain electrode) formed at the two ends of the semiconductor body in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by the gate structure in the vertical direction (the z-direction). As a result, one or more channels (not shown) of vertical transistor 132 can be formed in the semiconductor body vertically between the source and drain when a gate voltage applied to the gate electrode of the gate structure is above the threshold voltage of vertical transistor 132.

In some implementations, the vertical transistors 132 can be single-gate transistors, in which the gate structure may be located at a single lateral side of the semiconductor body, for example, for the purpose of increasing the transistor and memory cell density. In some other implementations, vertical transistor 132 can be a multi-gate transistor. That is, the gate structure can be laterally located at more than one side of the semiconductor body to form more than one gate, such that more than one channel can be formed between the source and drain in operation. That is, different from the planar transistor that includes only a single planar gate (and results in a single planar channel), vertical transistor 132 shown in FIG. 1 can include multiple vertical gates on multiple lateral sides of the semiconductor body due to the semiconductor structure of semiconductor body and gate structure that locates on the multiple lateral sides of the semiconductor body. Compared with planar transistors, vertical transistor 132 shown in FIG. 1 can have a larger gate control area to achieve better channel control with a smaller subthreshold swing. During the off state, since the channel is fully depleted, the leakage current of vertical transistor 132 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and gate-all-around (GAA) vertical transistors.

As shown in FIG. 1, storage unit 134 can be coupled to the source or the drain of vertical transistor 132. Storage unit 134 can include any devices that are capable of storing binary data (e.g., 0 and 1), including but not limited to, capacitors for DRAM cells and FRAM cells, and PCM elements for PCM cells. Peripheral circuits 120 can be coupled to memory cell array 110 through bit lines 150, word lines 140, and any other suitable metal wirings. As described above, peripheral circuits 120 can include any suitable circuits for facilitating the operations of memory cell array 110 by applying and sensing voltage signals and/or current signals through word lines 140 and bit lines 150 to and from each memory cell 130. Peripheral circuits 120 can include various types of peripheral circuits formed using CMOS technologies.

In some implementations, storage unit 134 can be pillar capacitors which are formed after forming the vertical transistors 132. Both the outer and inner surfaces of a pillar capacitor can be utilized as effective capacitor areas. This structure can be utilized to achieve greater packing density in a memory device. In some other implementations, storage unit 134 can be cup capacitors, which are formed before forming the vertical transistors 132. In such implementations, the high-temperature processes of forming the cup capacitors do not affect the formation of vertical transistors 132. Thus, metal oxide semiconductors can be employed as the channel structures of vertical transistors 132.

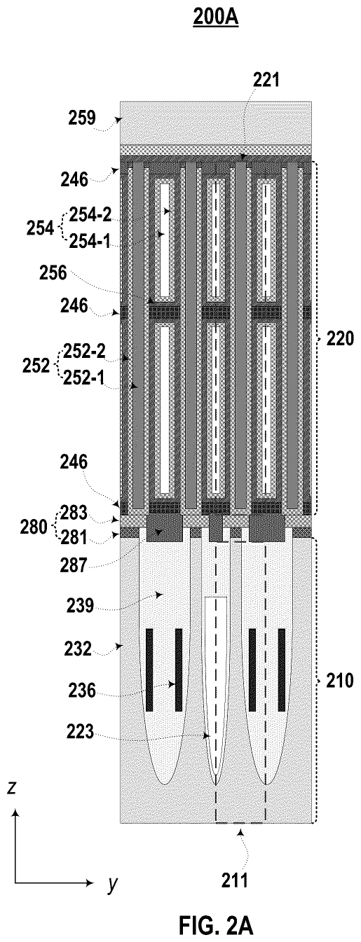

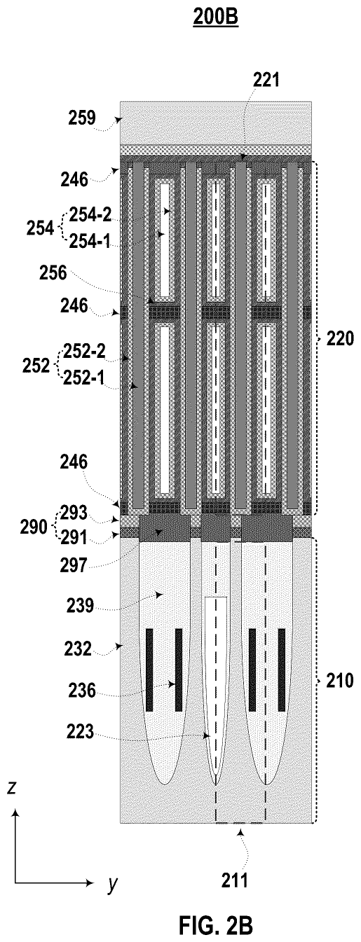

FIG. 2A illustrates a side view of a cross-section of a memory device 200A, according to some aspects of the present disclosure. It is understood that FIG. 2A is for illustrative purposes only and may not necessarily reflect the actual device structure (e.g., interconnections) in practice. Memory device 200A can be a DRAM memory device including an array of DRAM cells, and a peripheral circuit layer (not shown) including the peripheral circuits of the memory device 200A.

As shown in FIG. 2A, memory device 200A can include a transistor layer 210 and a storage layer 220 formed on a carrier substrate 259. In some implementations, the transistor layer 210 includes an array of transistors 211, and the storage layer 220 includes an array of capacitors 221. That is, each DRAM cell can include a capacitor 221 and a transistor 211 coupled with the capacitor 221. In some implementations, an array of source node contact (SNC) structures 280 are coupled between the array of transistors 211 and the array of capacitors 221.

In some implementations, the transistor layer 210 includes an array of transistor 211 (e.g., a MOSFET) configured to switch a respective DRAM cell. In some implementations, each transistor 211 includes a semiconductor body 232 (i.e., the active region in which multiple channels can form) extending vertically (in the z-direction), and a gate structure located at one or more lateral sides of semiconductor body 232. In some implementations, semiconductor body 232 can include any suitable semiconductor material, such as monocrystalline silicon, polycrystalline silicon, or silicon-germanium. In some other implementations, the leakage value of the semiconductor body 232 is lower than a pico-ampere. For example, semiconductor body 232 can include a metal oxide semiconductor material, such as InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn₂O, GaₓZn_{y}Sn_{z}O, AlₓZn_{y}Sn_{z}O, YbₓGa_{y}Zn₂O, InₓGa_{y}O, etc. In some implementations, adjacent semiconductor bodies 232 can be laterally separated from each other by an isolation structure 223 including isolation oxides (TISO) and/or air gaps.

In some implementations, semiconductor body 232 extends in a vertical direction (the z-direction), and includes a source and a drain disposed at the two ends (the upper end and lower end) of semiconductor body 232, respectively. Source and drain can be doped with N-type dopants (e.g., P or As) or P-type dopants (e.g., B or Ga) at a desired doping level. In some implementations, the source is coupled to capacitor 221 through SNC structure 280, and the drain is coupled to a bit line (not shown). In some implementations, the sources of adjacent semiconductor bodies 232 can be laterally separated from each other by an insulating layer 239 including any suitable dielectric material (e.g., silicon oxide). In some implementations, the drains of semiconductor bodies 232 of a column of DRAM cells along the bit line direction (i.e., the y-direction) can be laterally connected with each other to form a common drain that is coupled to a common bit line (not shown), which extends in the bit line direction (the y-direction).

In some implementations, the gate structure of transistor 211 includes a gate dielectric and a gate electrode 236. In some implementations, the gate dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 236 includes conductive materials including, but not limited to, W, Co, Cu, Al, TiN, TaN, polysilicon, silicide, or any combination thereof. In some implementations, gate electrode 236 includes multiple conductive layers, such as a W layer over a TiN layer. In one example, the gate structure may be a “gate oxide/gate poly” gate in which the gate dielectric includes silicon oxide, and the gate electrode 236 includes doped polysilicon. In another example, the gate structure may be a high-k metal gate (HKMG) in which the gate dielectric includes a high-k dielectric, and the gate electrode 236 includes a metal. In some implementations, the gate structures of adjacent semiconductor bodies 232 can be laterally separated from each other by the insulating layer 239.

In some implementations, the gate electrode 236 may be part of a word line or extend in the word line direction (the x-direction) as a word line. Each word line can extend in the word line direction (the x-direction), and be coupled to a row of DRAM cells. That is, the bit line and the word line can extend in two perpendicular lateral directions, and semiconductor body 232 of transistor 211 can extend in the vertical direction perpendicular to the two lateral directions in which the bit line and the word line extend.

As shown in FIG. 2A, in some implementations, SNC structure 280 can include a silicide layer 281 in contact with a doped end of the corresponding semiconductor body 232 to form an Ohmic contact with the source end of transistor 211 to decrease contact resistance. In some implementations, the silicide layer 281 can include any suitable silicide material, such as Titanium Silicide (TiSi₂), Cobalt Silicide (CoSi₂), Nickel Silicide (NiSi), Tungsten Silicide (WSi₂), Platinum Silicide (PtSi), Molybdenum Silicide (MoSi₂), Chromium Silicide (CrSi₂), etc. In some implementations, silicide layer 281 can have a thickness in the vertical direction in a range between about 2 nm and about 25 nm.

In some implementations, SNC structure 280 may include a conductive layer 283 in contact with a corresponding capacitor 221. In some implementations, conductive layer 283 can include any suitable conductive materials, such as polysilicon, Al, Cu, W, etc. In some implementations, when the conductive layer 283 is a metal layer, such as a Cu layer, the SNC structure 280 may further include a barrier layer (e.g., TiN layer, TaN layer, etc., not shown) to prevent the metal atoms from diffusing into silicon or dielectric layers. In some implementations, conductive layer 283 can have a thickness in the vertical direction in a range between about 2 nm and about 25 nm. In some implementations, a vertical distance between the silicide layer 281 of each SNC structure 280 and the gate electrode 236 of the corresponding transistor 211 is in a range from about 40 nm to about 70 nm. In some implementations, SNC structure 280 can have a thickness in the vertical direction in a range between about 10 nm and about 30 nm.

In some implementations, a sidewall of the silicide layer 281 of SNC structure 280 is vertically aligned with a sidewall of the corresponding semiconductor body 232, and the semiconductor body 232 has a cylinder shape without an enlarged end adjacent to the silicide layer 281. In some implementations, the semiconductor body 232 and the SNC structure 280 can be coaxial. In some implementations, a protection layer 287 can be located between adjacent SNC structures 280 to separate the array of SNC structures 280 from each other. The protection layer 287 can include any suitable dielectric material different from the material of the insulating layer 239. For example, the protection layer 287 can include silicon nitride. In some implementations, the thickness of the protection layer 287 in the vertical direction can be in a range between about 20 nm and about 30 nm.

In some implementations, the insulating layer 239 can extend in between the silicide layer 281 and the protection layer 287. A first lateral dimension of the silicide layer 281 is less than a second lateral dimension of the conductive layer 283. In some implementations, a lateral dimension of the portion of the insulating layer 239 between the silicide layer 281 and the protection layer 287 can be in a range between about 2 nm and about 5 nm. In some implementations, a lateral size of semiconductor body 232 along the y-direction can be in a range between about 7 nm to about 13 nm, and a lateral size of SNC structure 280 along the y-direction can be in a range between about 14 nm to about 22 nm. In some implementations, a lateral size of semiconductor body 232 along the x-direction can be in a range between about 15 nm to about 20 nm, and a lateral size of SNC structure 280 along the x-direction can be in a range between about 22 nm to about 30 nm.

Capacitors 221 can include a first electrode 252, a second electrode 254, and a dielectric layer 256 formed between first electrode 252 and second electrode 254. First electrode 252 can have a hollow cylinder shape structure fixed in a mesh structure 246. Capacitor 221 can be a vertical capacitor in which first and second electrodes 252 and 254, and dielectric layer 256 extend vertically (in the z-direction), and dielectric layer 256 can be sandwiched between first and second electrodes 252 and 254. In some implementations, the second electrodes 254 are connected with each other and function as a common electrode, while each first electrode 252 is coupled to a source of a respective transistor 211 in the same DRAM cell through the SNC structure 280.

In some implementations, first electrodes 252 and/or the second electrode 254 can include conductive materials including, but not limited to, W, Co, Cu, Al, TiN, TaN, polysilicon, silicide, or any combination thereof. In some implementations, first electrodes 252 and/or the second electrode 254 include a multiple-layer structure, each layer of the multiple-layer structure comprising one of TiN, TaN, carbon, polysilicon, metal, metal compounds, and silicide. For example, the first electrode 252 can include a polysilicon layer 252-1 and a TiN layer 252-2, and the second electrode 254 can include a GeSi layer 254-1 and a TiN layer 254-2. In some implementations, dielectric layer 256 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof.

In some implementations, memory device 200A can further include any other suitable components that are not illustrated in FIG. 2A. For example, in some implementations, memory device 200A can further include one or more interconnect layers including interconnect structures to electrically connect the word lines, the bit lines, the first and second electrodes of the capacitors, etc., to transfer electrical signals. In some implementations, the one or more interconnect layers can include lateral interconnect lines and vertical interconnect access (VIA) contacts. In some implementations, the one or more interconnect layers can also include local interconnects, such as bit line contacts, word line contacts, and capacitor contacts. As used herein, the term “interconnects” can broadly include any suitable types of interconnects, such as middle-end-of-line (MEOL) interconnects and back-end-of-line (BEOL) interconnects. The one or more interconnect layers can further include one or more interlayer dielectric (ILD) layers (also known as “intermetal dielectric (IMD) layers”) in which the interconnect lines and via contacts can form. That is, the one or more interconnect layers can include interconnect lines and via contacts in multiple ILD layers. The interconnects in the one or more interconnect layers can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

FIG. 2B illustrates a side view of a cross-section of a memory device 200B, according to some aspects of the present disclosure. It is understood that FIG. 2B is for illustrative purposes only and may not necessarily reflect the actual device structure (e.g., interconnections) in practice. Memory device 200B can be a DRAM memory device including an array of DRAM cells, and a peripheral circuit layer (not shown) including the peripheral circuits of the memory device 200B.

As shown in FIG. 2B, memory device 200B can include a transistor layer 210 and a storage layer 220 formed on a carrier substrate 259. In some implementations, the transistor layer 210 includes an array of transistors 211, and the storage layer 220 includes an array of capacitors 221. That is, each DRAM cell can include a capacitor 221 and a transistor 211 coupled with the capacitor 221. In some implementations, an array of source node contact (SNC) structures 290 are coupled between the array of transistors 211 and the array of capacitors 221.

In some implementations, the transistor layer 210 includes an array of transistor 211 (e.g., a MOSFET) configured to switch a respective DRAM cell. In some implementations, each transistor 211 includes a semiconductor body 232 (i.e., the active region in which multiple channels can form) extending vertically (in the z-direction), and a gate structure located at one or more lateral sides of semiconductor body 232. In some implementations, semiconductor body 232 can include any suitable semiconductor material, such as monocrystalline silicon, polycrystalline silicon, or silicon-germanium. In some other implementations, the leakage value of the semiconductor body 232 is lower than a pico-ampere. For example, semiconductor body 232 can include a metal oxide semiconductor material, such as InₓGa_{y}Zn_{z}O, InₓGa_{y}Si_{z}O, InₓSn_{y}Zn₂O, InₓZn_{y}O, ZnₓO, ZnₓSn_{y}O, ZnₓO_{y}N, ZrₓZn_{y}Sn_{z}O, SnₓO, HfₓIn_{y}Zn₂O, GaₓZn_{y}Sn₂O, AlₓZn_{y}Sn_{z}O, YbₓGa_{y}Zn₂O, InₓGa_{y}O, etc. In some implementations, adjacent semiconductor bodies 232 can be laterally separated from each other by an isolation structure 223 including TISO and/or air gaps.

In some implementations, semiconductor body 232 extends in a vertical direction (the z-direction), and includes a source and a drain disposed at the two ends (the upper end and lower end) of semiconductor body 232, respectively. Source and drain can be doped with N-type dopants (e.g., P or As) or P-type dopants (e.g., B or Ga) at a desired doping level. In some implementations, the source is coupled to capacitor 221 through SNC structure 280, and the drain is coupled to a bit line (not shown). In some implementations, the sources of adjacent semiconductor bodies 232 can be laterally separated from each other by an insulating layer 239 including any suitable dielectric material (e.g., silicon oxide). In some implementations, the drains of semiconductor bodies 232 of a column of DRAM cells along the bit line direction (i.e., the y-direction) can be laterally connected with each other to form a common drain that is coupled to a common bit line (not shown), which extends in the bit line direction (the y-direction).

In some implementations, the gate structure of transistor 211 includes a gate dielectric and a gate electrode 236. In some implementations, the gate dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 236 includes conductive materials including, but not limited to, W, Co, Cu, Al, TiN, TaN, polysilicon, silicide, or any combination thereof. In some implementations, gate electrode 236 includes multiple conductive layers, such as a W layer over a TiN layer. In one example, the gate structure may be a “gate oxide/gate poly” gate in which the gate dielectric includes silicon oxide, and the gate electrode 236 includes doped polysilicon. In another example, the gate structure may be a high-k metal gate (HKMG) in which the gate dielectric includes a high-k dielectric, and the gate electrode 236 includes a metal. In some implementations, the gate structures of adjacent semiconductor bodies 232 can be laterally separated from each other by the insulating layer 239.

In some implementations, the gate electrode 236 may be part of a word line or extend in the word line direction (the x-direction) as a word line. Each word line can extend in the word line direction (the x-direction), and be coupled to a row of DRAM cells. That is, the bit line and the word line can extend in two perpendicular lateral directions, and semiconductor body 232 of transistor 211 can extend in the vertical direction perpendicular to the two lateral directions in which the bit line and the word line extend.

As shown in FIG. 2B, in some implementations, SNC structure 290 can include a silicide layer 291 in contact with a doped end of the corresponding semiconductor body 232 to form an Ohmic contact with the source end of transistor 211 to decrease contact resistance. In some implementations, the silicide layer 291 can include any suitable silicide material, such as TiSi₂, CoSi₂, NiSi, WSi₂, PtSi, MoSi₂, CrSi₂, etc. In some implementations, silicide layer 291 can have a thickness in the vertical direction in a range between about 2 nm and about 25 nm. In some implementations, SNC structure 290 may include a conductive layer 293 in contact with a corresponding capacitor 221. In some implementations, conductive layer 293 can include any suitable conductive materials, such as polysilicon, Al, Cu, W, etc. In some implementations, when the conductive layer 293 is a metal layer, such as a Cu layer, the SNC structure 290 may further include a barrier layer (e.g., TiN layer, TaN layer, etc., not shown) to prevent the metal atoms from diffusing into silicon or dielectric layers. In some implementations, conductive layer 293 can have a thickness in the vertical direction in a range between about 2 nm and about 25 nm. In some implementations, a vertical distance between the silicide layer 291 of each SNC structure 290 and the gate electrode 236 of the corresponding transistor 211 is in a range from about 40 nm to about 70 nm. In some implementations, SNC structure 290 can have a thickness in the vertical direction in a range between about 10 nm and about 30 nm.

In some implementations, a sidewall of the silicide layer 291 and the conductive layer 293 of SNC structure 290 is vertically aligned with a sidewall of the corresponding semiconductor body 232, and the semiconductor body 232 has a cylinder shape without an enlarged end adjacent to the silicide layer 291. In some implementations, the semiconductor body 232 and the SNC structure 290 can be coaxial. In some implementations, a protection layer 297 can be located between adjacent SNC structures 290 to separate the array of SNC structures 290 from each other. The protection layer 297 can include any suitable dielectric material different from the material of the insulating layer 239. For example, the protection layer 297 can include silicon nitride. In some implementations, the thickness of the protection layer 297 in the vertical direction can be in a range between about 20 nm and about 30 nm. In some implementations, a lateral size of semiconductor body 232 along the y-direction can be in a range between about 7 nm to about 13 nm, and a lateral size of SNC structure 290 along the y-direction can be in a range between about 7 nm to about 13 nm. In some implementations, a lateral size of semiconductor body 232 along the x-direction can be in a range between about 15 nm to about 20 nm, and a lateral size of SNC structure 290 along the x-direction can be in a range between about 15 nm to about 20 nm.

Capacitors 221 can include a first electrode 252, a second electrode 254, and a dielectric layer 256 formed between first electrode 252 and second electrode 254. First electrode 252 can have a hollow cylinder shape structure fixed in a mesh structure 246. Capacitor 221 can be a vertical capacitor in which the first and second electrodes 252 and 254, and dielectric layer 256 extend vertically (in the z-direction), and dielectric layer 256 can be sandwiched between first and second electrodes 252 and 254. In some implementations, the second electrodes 254 are connected with each other and function as a common electrode, while each first electrode 252 is coupled to a source of a respective transistor 211 in the same DRAM cell through the SNC structure 290.

In some implementations, first electrodes 252 and/or the second electrode 254 can include conductive materials including, but not limited to, W, Co, Cu, Al, TiN, TaN, polysilicon, silicide, or any combination thereof. In some implementations, first electrodes 252 and/or the second electrode 254 include a multiple-layer structure, each layer of the multiple-layer structure comprising one of TiN, TaN, carbon, polysilicon, metal, metal compounds, and silicide. For example, the first electrode 252 can include a polysilicon layer 252-1 and a TiN layer 252-2, and the second electrode 254 can include a GeSi layer 254-1 and a TiN layer 254-2. In some implementations, dielectric layer 256 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, memory device 200B can further include any other suitable components that are not illustrated in FIG. 2B. For example, in some implementations, memory device 200B can further include one or more interconnect layers including interconnect structures to electrically connect the word lines, the bit lines, the first and second electrodes of the capacitors, etc., to transfer electrical signals. In some implementations, the one or more interconnect layers can include lateral interconnect lines and VIA contacts. In some implementations, the one or more interconnect layers can also include local interconnects, such as bit line contacts, word line contacts, and capacitor contacts. As used herein, the term “interconnects” can broadly include any suitable types of interconnects, such as MEOL interconnects and BEOL interconnects. The one or more interconnect layers can further include one or more ILD layers in which the interconnect lines and via contacts can form. That is, the one or more interconnect layers can include interconnect lines and via contacts in multiple ILD layers. The interconnects in the one or more interconnect layers can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

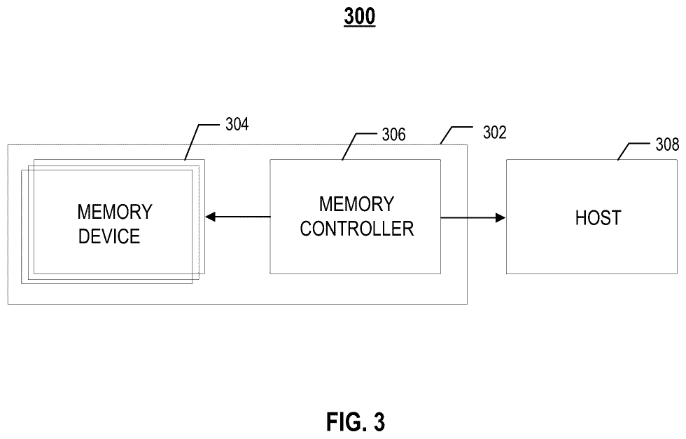

FIG. 3 illustrates a block diagram of a system 300 having a memory device, according to some implementations of the present disclosure. System 300 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 3, system 300 can include a host 308 and a memory system 302 having one or more memory devices 304 and a memory controller 306. Host 308 can be a processor of an electronic device, such as a central processing unit (CPU), or a system-on-chip (SoC), such as an application processor (AP). Host 308 can be configured to send or receive the data to or from memory devices 304. Memory device 304 can be any memory device disclosed herein, such as memory device 100. In some implementations, memory device 304 can include one or more of the memory devices 200A/200B shown in FIGS. 2A-2B as described above in detail.

Memory controller 306 is coupled to memory device 304 and host 308 and is configured to control memory device 304, according to some implementations. Memory controller 306 can manage the data stored in memory device 304 and communicate with host 308. Memory controller 306 can be configured to control operations of memory device 304, such as read, write, and refresh operations. Memory controller 306 can also be configured to manage various functions with respect to the data stored or to be stored in memory device 304 including, but not limited to refresh and timing control, command/request translation, buffer and schedule, and power management. In some implementations, memory controller 306 is further configured to determine the maximum memory capacity that the computer system can use, the number of memory banks, memory type and speed, memory particle data depth and data width, and other important parameters. Any other suitable functions may be performed by memory controller 306 as well. Memory controller 306 can communicate with an external device (e.g., host 308) according to a particular communication protocol. For example, memory controller 306 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

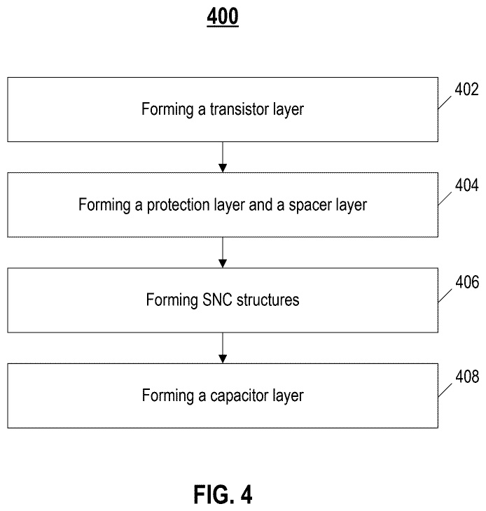

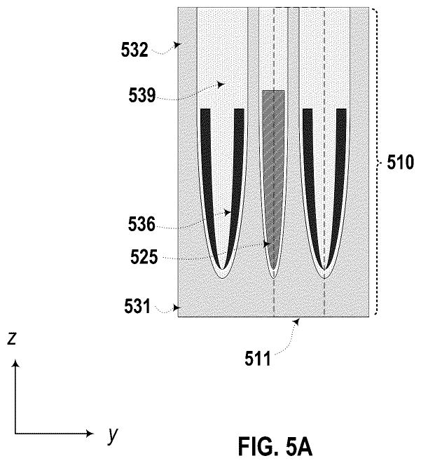

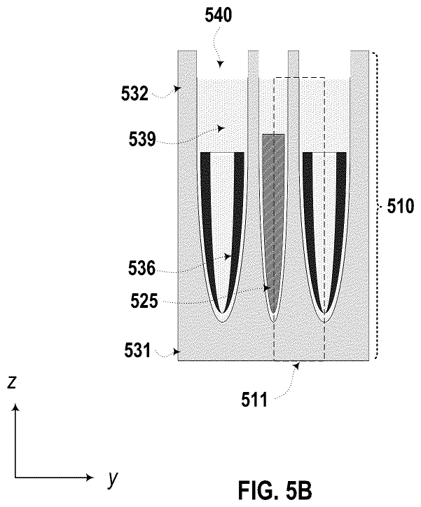

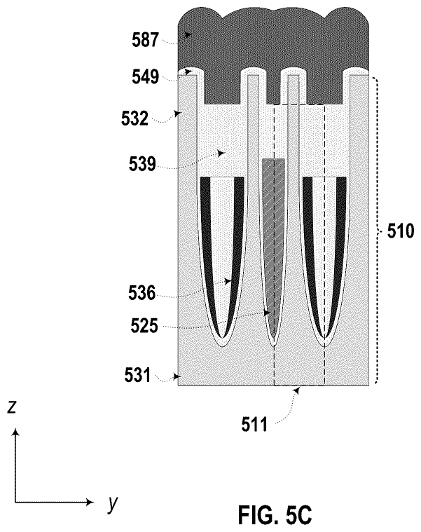

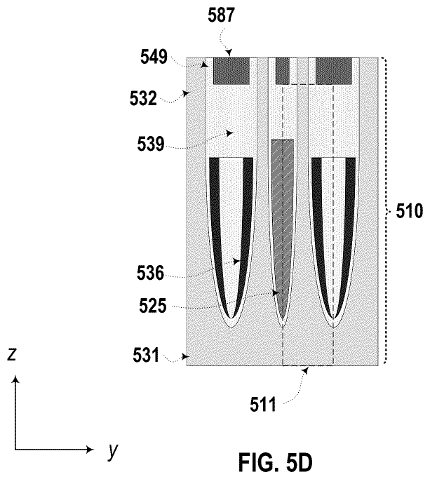

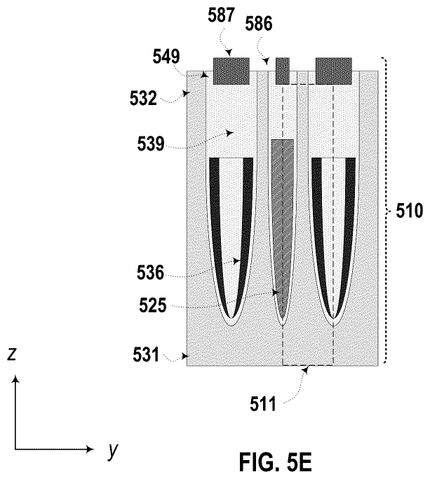

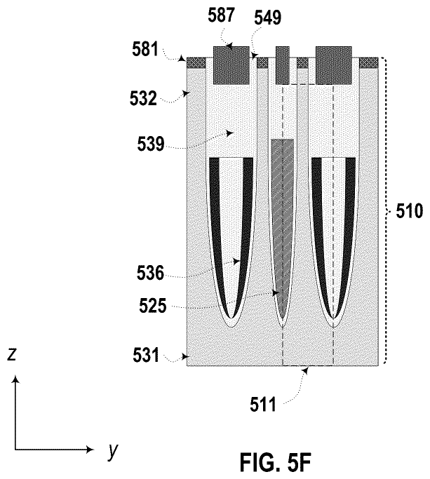

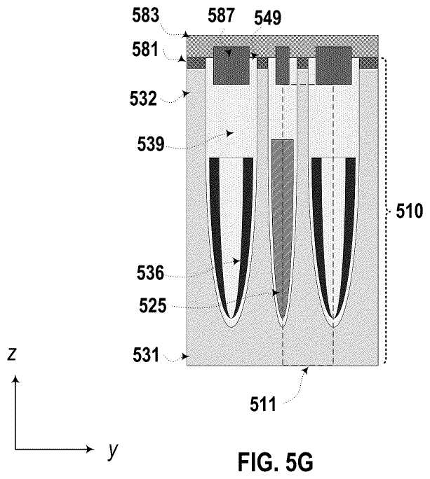

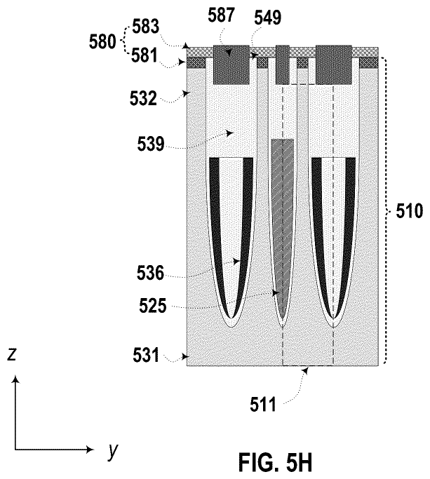

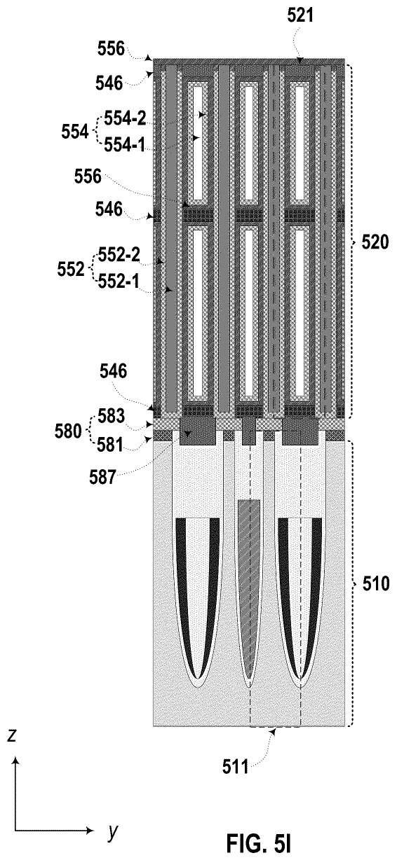

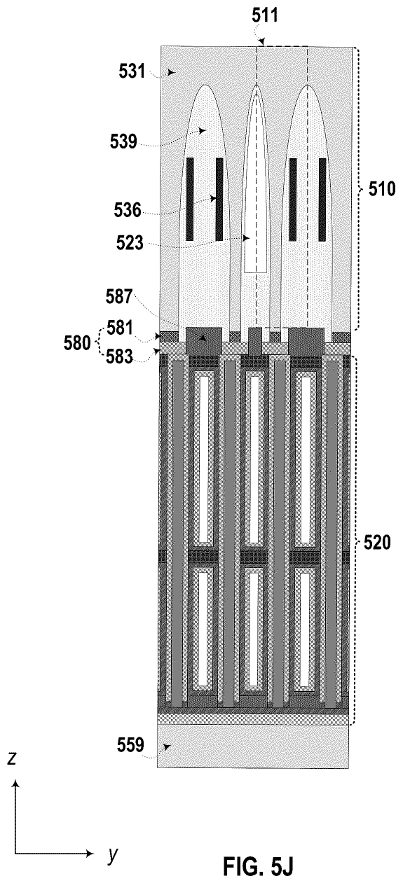

FIG. 4 illustrates a flowchart of a fabricating method 400 for forming a memory device including DRAM cells, according to some implementations of the present disclosure. FIGS. 5A-5J illustrate schematic views of a memory device at certain fabricating stages of the method 400 shown in FIG. 4, according to various implementations of the present disclosure. It is understood that the operations shown in method 400 are not exhaustive and that other operations can be performed as well before, after, or between any of the illustrated operations. Further, some of the operations may be performed simultaneously, or in a different order than shown in FIG. 4.

As shown in FIG. 4, method 400 can start at operation 402, in which a transistor layer can be formed. FIG. 5A illustrates a schematic side cross-sectional view of a semiconductor structure in the y-z plane after operation 402 of method 400. In some implementations, as shown in FIG. 5A, forming the transistor layer 510 comprises forming an array of vertical transistors 511.

In some implementations, forming transistor layer 510 comprises forming a plurality of semiconductor bodies 532 extending vertically on a semiconductor layer 531. In some implementations, the plurality of semiconductor bodies 532 can be formed by patterning a semiconductor substrate using any suitable patterning processes (e.g., photoetching, dry etching, wet etching, cleaning, chemical mechanical polishing (CMP), etc.) to form trenches laterally extending along the x-direction and the y-direction, the remaining vertical portions of the semiconductor substrate between the trenches form the semiconductor bodies 532, and the remaining lateral portion of the semiconductor substrate below the trenches form the semiconductor layer 531. In some implementations, TISO structures 525 can be formed in the trenches to laterally separate adjacent semiconductor bodies 532.

The semiconductor bodies 532 can be used to form channels of the vertical transistors 511. In some implementations, the semiconductor body bodies 532 and the semiconductor layer 531 can be formed by using any suitable semiconductor material, such as monocrystalline silicon, polycrystalline silicon, or silicon-germanium. In some other implementations, the semiconductor body bodies 532 and the semiconductor layer 531 can be formed by using any suitable metal oxide semiconductor material, such as InₓGa_{y}Zn₂O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn₂O, GaₓZn_{y}Sn_{z}O, AlₓZn_{y}Sn_{z}O, YbₓGa_{y}Zn_{z}O, InₓGa_{y}O, etc.

In some implementations, forming the transistor layer 510 further comprises forming gate structures of vertical transistor 511. In some implementations, forming the gate structures includes forming a gate dielectric and forming a gate electrode 536. In some implementations, the gate dielectric and the gate electrode 536 can be formed by any suitable deposition processes (e.g., chemical vapor deposition (CVD), physical vapor deposition (PVD), atomic layer deposition (ALD), etc.). In some implementations, forming the gate dielectric can include depositing any suitable dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, forming gate electrode 536 includes depositing one or more layers of conductive materials including, but not limited to, W, Co, Cu, Al, TiN, TaN, polysilicon, silicide, or any combination thereof. In some implementations, forming the transistor layer 510 further comprises forming an insulating layer 539 to fill the trenches between adjacent gate structures and/or adjacent semiconductor bodies 532.

Referring back to FIG. 4, method 400 can proceed to operation 404, in which a protection layer and a spacer layer can be formed between ends of the semiconductor bodies of the vertical transistors. FIGS. 5B-5D illustrate schematic side cross-sectional views of the semiconductor structure in the y-z plane at various stages of operation 404 of method 400.

In some implementations, as shown in FIG. 5B, portions of the insulating layer 539 can be removed to form first recesses 540 between the ends of the semiconductor bodies 532 of the vertical transistors 511, such that the sidewalls of the ends of the semiconductor bodies 532 are exposed by the first recesses 540. In some implementations, the first recesses 540 can be formed by using any suitable etching processes (e.g., dry etching, wet etching, etc.) to remove portions of the insulating layer 539.

In some implementations, as shown in FIG. 5C, a spacer layer 549 can be formed to cover the top surfaces and the sidewalls of the ends of the semiconductor bodies 532, and a protection layer 587 can be formed on the spacer layer 549 to fill the first recesses 540. In some implementations, the spacer layer 549 and the protection layer 587 can be formed by any suitable deposition processes (e.g., CVD, PVD, ALD, etc.). In some implementations, spacer layer 549 can include a first dielectric material, such as silicon oxide, which is the same as the material in the insulation layer 539. In some implementations, the protection layer 587 can include a second dielectric material, such as silicon nitride, which is different from the material in the insulation layer 539.

In some implementations, as shown in FIG. 5D, portions of the spacer layer 549 and the protection layer 587 can be removed to expose the top surfaces of the ends of the semiconductor bodies 532. In some implementations, the portions of the spacer layer 549 and the protection layer 587 above the top surfaces of the ends of the semiconductor bodies 532 can be removed by using any suitable method, such as a CMP process. As such, the top surfaces of the ends of the semiconductor bodies 532, the spacer layer 549, and the protection layer 587 can be coplanar.

Referring back to FIG. 4, method 400 can proceed to operation 406, in which SNC structures can be formed on source ends of the semiconductor bodies of the vertical transistors. FIGS. 5E-5H illustrate schematic side cross-sectional views of the semiconductor structure in the y-z plane at various stages of operation 406 of method 400.

In some implementations, as shown in FIG. 5E, portions of the spacer layer 549 and the ends of the semiconductor bodies 532 can be removed to form second recesses 586. In some implementations, the second recesses 586 can be formed by using any suitable etching processes (e.g., dry etching, wet etching, etc.) and cleaning processes (e.g., Standard Clean 1 (SC1)) to remove portions of the spacer layer 549 and the ends of the semiconductor bodies 532. In some implementations, the exposed ends of the semiconductor bodies 532 can be doped with N-type dopants (e.g., P or As) or P-type dopants (e.g., B or Ga) at a desired doping level by using any suitable ion implantation process to form sources of the vertical transistors 511.

In some implementations, as shown in FIG. 5F, a silicide layer 581 can be formed on the source ends of the semiconductor bodies 532 of the vertical transistors 511. In some implementations, the silicide layer 581 can be formed by any suitable process, such as rapid thermal annealing (RTA). For example, a thin layer of metal (e.g., Ti, Co, or Ni) can be deposited on the source ends of the semiconductor bodies 532 of the vertical transistors 511 using methods such as sputtering or CVD. A first low-temperature RTA process (also referred to as an initial RTA or a pre-RTA) may be performed to form an intermediate phase of silicide (e.g., TiSi for titanium silicide, NiSi for nickel silicide, CoSi for cobalt silicide). A cleaning process can then be performed to remove extra metal materials. Next, a second high-temperature RTA process can be performed to complete the formation of the silicide layer 581 and activate the dopants of the source ends of the semiconductor bodies 532 of the vertical transistors 511.

In some implementations, as shown in FIG. 5G, a conductive layer 583 can be formed to cover the silicide layer 581 and protection layer 587. In some implementations, the conductive layer 583 can be a polysilicon layer or a metal layer formed by any suitable thin film deposition process (e.g., CVD, PVD, ALD, etc.). In some implementations, as shown in FIG. 5H, portions of the conductive layer 583 can be removed by any suitable process (e.g., wet etching, dry etching, CMP, etc.), such that the top surface of the conductive layer 583 is lower than the top surface of the protection layer 587. The silicide layer 581 and the conductive layer 583 in each second recess 586 can constitute an SNC structure 580.

Referring back to FIG. 4, method 400 can proceed to operation 408, in which a storage layer can be formed on the SNC structures and the protection layer. FIG. 5I illustrates a schematic side cross-sectional view of the semiconductor structure in the y-z plane after operation 408 of method 400.

As shown in FIG. 5I, forming the first semiconductor stack can further comprise forming a storage layer 520 vertically stacked on the SNC structures 580 and the protection layer 587. In some implementations, forming storage layer 520 comprises forming an array of capacitors 521 each coupled with a corresponding one of the array of vertical transistors 511. In some implementations, forming the array of capacitors 521 comprises forming a first electrode 552, forming a second electrode 554, and forming a dielectric layer 556 formed between first electrode 552 and second electrode 554 by any suitable thin film deposition processes (e.g., CVD, PVD, ALD, etc.).

In some implementations, a mesh structure 546 can be formed in a sacrificial layer (not shown), and a plurality of through holes (not shown) can be formed in the sacrificial layer. The first electrode 552 can be formed by depositing one or more layers of conductive materials including, but not limited to, W, Co, Cu, Al, TiN, TaN, polysilicon, silicide, or any combination thereof, to form a hollow cylinder shape structure in the through holes and being fixed in a mesh structure 546. Each first electrode 552 can be in contact with the conductive layer 583 of a corresponding one of the array of SNC structures 580. In some implementations, forming the first electrode 552 can include forming a polysilicon layer 552-1 and a TiN layer 552-2, as shown in FIG. 5I. The dielectric layer 556 can be formed by depositing a high-k material (e.g., Al₂O₃, HfO₂, Ta₂O₅, ZrO₂, TiO₂) to cover the first electrode 552. The sacrificial layer can then be removed, and the second electrodes 554 can be formed on the dielectric layer 556. In some implementations, the second electrodes 554 can be formed by depositing one or more layers of conductive materials including, but not limited to, W, Co, Cu, Al, TiN, TaN, polysilicon, silicide, or any combination thereof. In some implementations, forming the second electrode 552 can include forming a GeSi layer 554-1 and a TiN layer 554-2. In some implementations, forming the storage layer 520 further comprises forming a lateral conductive layer coupled with the array of second electrodes 554 to form a common second electrode of the array of capacitors 521.

It is noted that, method 400 can further include any other suitable operations that are not shown in FIG. 4. For example, as shown in FIG. 5J, method 400 can further include forming a carrier substrate 559 on the storage layer 520, flipping the formed structure, removing the semiconductor layer 531, portions of the insulating layer 539, and portions of the gate electrode 536. In some implementations, the TISO can be partially removed to form one or more air gaps 523. Portions of the insulating layer 539 and the semiconductor layer 531 can then be reformed to cover the gate electrode 536. In some implementations, semiconductor layer 531 can be doped with N-type dopants (e.g., P or As) or P-type dopants (e.g., B or Ga) at a desired doping level to form a common drain of a column of vertical transistors 511. In some implementations, method 400 can further include forming bit lines coupled with semiconductor layer 531. In some implementations, method 400 can further include forming one or more interconnection layers.

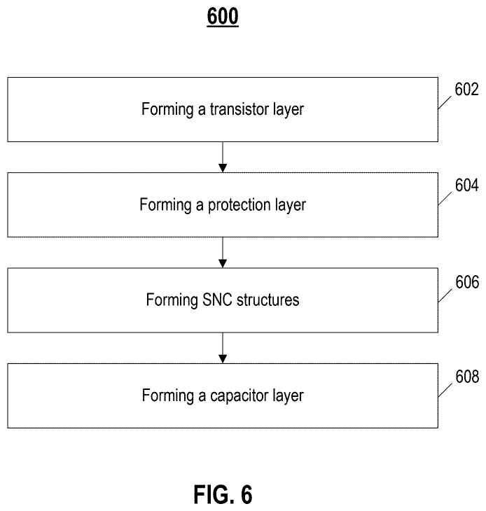

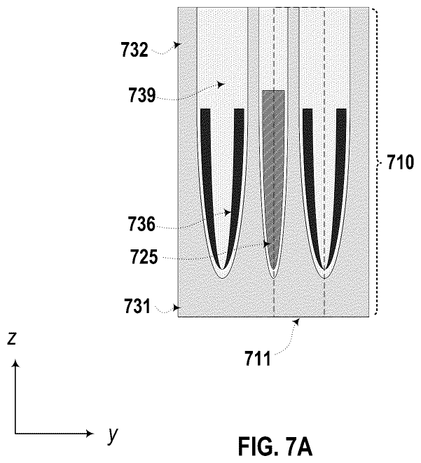

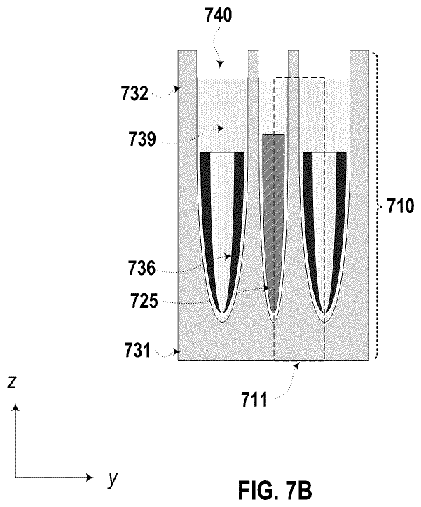

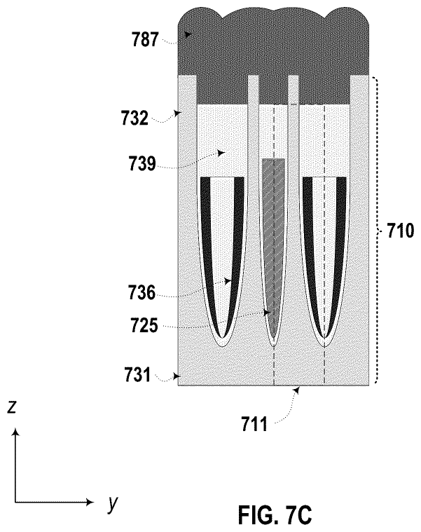

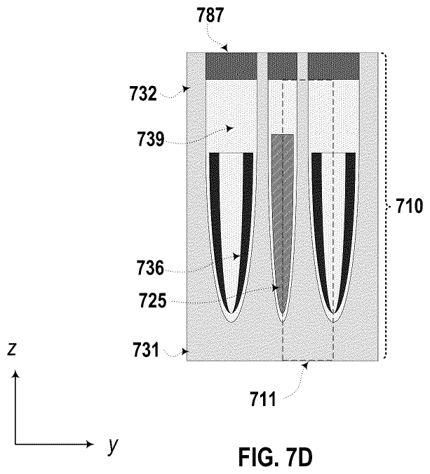

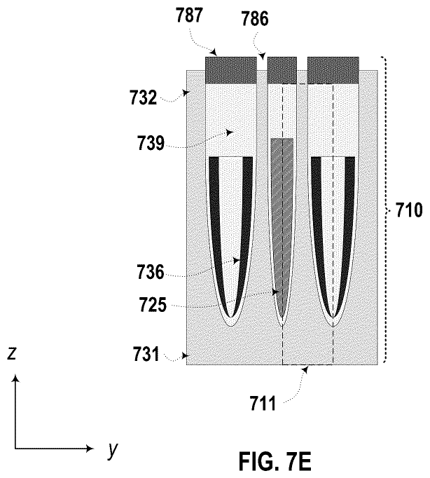

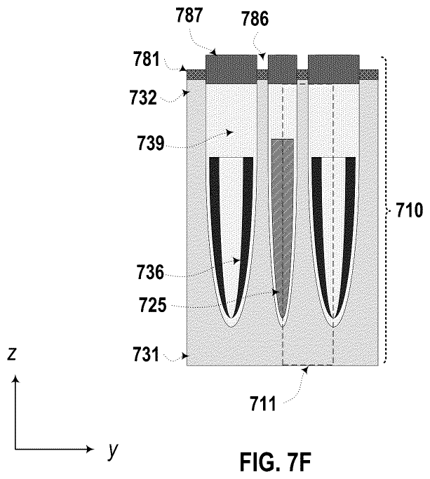

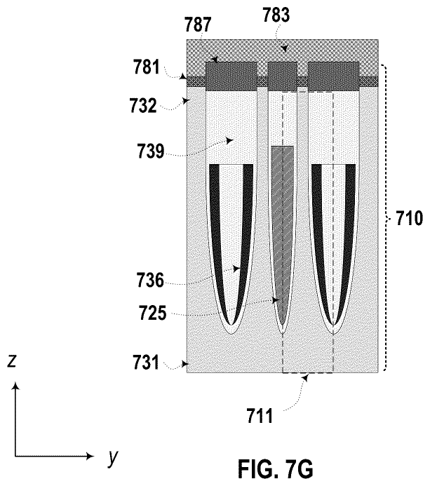

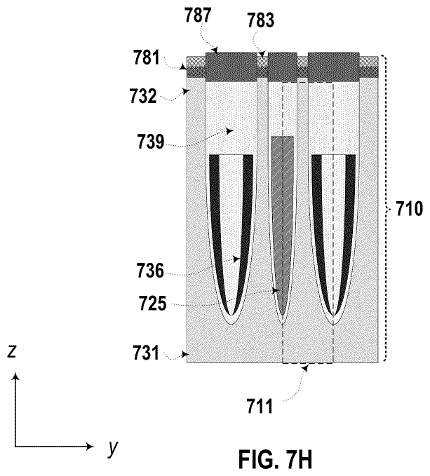

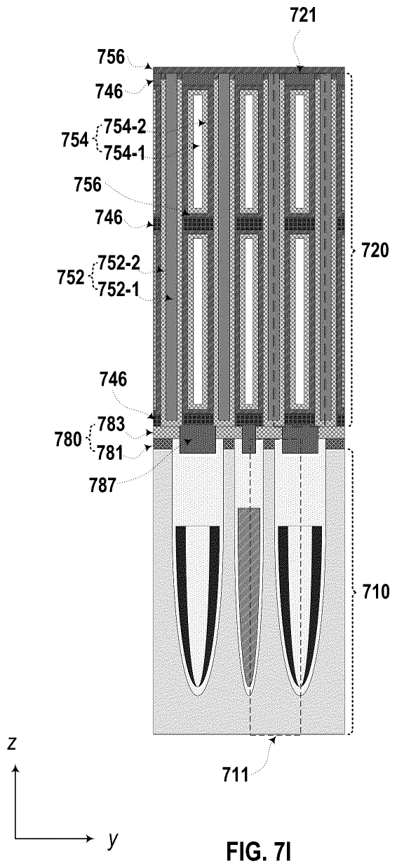

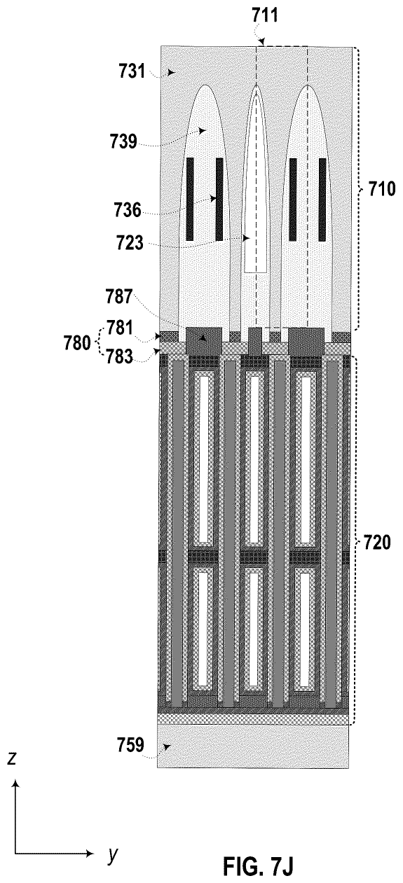

FIG. 6 illustrates a flowchart of a fabricating method 600 for forming a memory device including DRAM cells, according to some implementations of the present disclosure. FIGS. 7A-7J illustrate schematic views of a memory device at certain fabricating stages of the method 600 shown in FIG. 6, according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIG. 6, method 600 can start at operation 602, in which a transistor layer can be formed. FIG. 7A illustrates a schematic side cross-sectional view of a semiconductor structure in the y-z plane after operation 602 of method 600. In some implementations, as shown in FIG. 7A, forming the transistor layer 710 comprises forming an array of vertical transistors 711.

In some implementations, forming the transistor layer 710 comprises forming a plurality of semiconductor bodies 732 extending vertically on a semiconductor layer 731. In some implementations, the plurality of semiconductor bodies 732 can be formed by patterning a semiconductor substrate using any suitable patterning processes (e.g., photoetching, dry etching, wet etching, cleaning, chemical mechanical polishing (CMP), etc.) to form trenches laterally extending along the x-direction and the y-direction, the remaining vertical portions of the semiconductor substrate between the trenches form the semiconductor bodies 732, and the remaining lateral portion of the semiconductor substrate below the trenches form the semiconductor layer 731. In some implementations, TISO structures 725 can be formed in the trenches to laterally separate adjacent semiconductor bodies 732.

The semiconductor bodies 732 can be used to form channels of the vertical transistors 711. In some implementations, the semiconductor bodies 732 and the semiconductor layer 731 can be formed by using any suitable semiconductor material, such as monocrystalline silicon, polycrystalline silicon, or silicon-germanium. In some other implementations, the semiconductor body bodies 732 and the semiconductor layer 731 can be formed by using any suitable metal oxide semiconductor material, such as InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc.

In some implementations, forming the transistor layer 710 further comprises forming gate structures of vertical transistor 711. In some implementations, forming the gate structures includes forming a gate dielectric and forming a gate electrode 736. In some implementations, the gate dielectric and the gate electrode 736 can be formed by any suitable deposition processes (e.g., CVD, PVD, ALD, etc.). In some implementations, forming the gate dielectric can include depositing any suitable dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, forming gate electrode 736 includes depositing one or more layers of conductive materials including, but not limited to, W, Co, Cu, Al, TiN, TaN, polysilicon, silicide, or any combination thereof. In some implementations, forming the transistor layer 710 further comprises forming an insulating layer 739 to fill the trenches between adjacent gate structures and/or adjacent semiconductor bodies 732.

Referring back to FIG. 6, method 600 can proceed to operation 604, in which a protection layer can be formed between the ends of the semiconductor bodies of the vertical transistors. FIGS. 7B-7D illustrate schematic side cross-sectional views of the semiconductor structure in the y-z plane at various stages of operation 604 of method 600.

In some implementations, as shown in FIG. 7B, portions of the insulating layer 739 can be removed to form first recesses 540 between the ends of the semiconductor bodies 732 of the vertical transistors 711, such that the sidewalls of the ends of the semiconductor bodies 732 are exposed by the first recesses 740. In some implementations, the first recesses 740 can be formed by using any suitable etching processes (e.g., dry etching, wet etching, etc.) to remove portions of the insulating layer 739.

In some implementations, as shown in FIG. 7C, a protection layer 787 can be formed to cover the top surfaces and the sidewalls of the ends of the semiconductor bodies 732, and to fill the first recesses 740. In some implementations, the protection layer 787 can be formed by any suitable deposition process (e.g., CVD, PVD, ALD, etc.). In some implementations, the protection layer 787 can include a dielectric material, such as silicon nitride, which is different from the material in the insulation layer 739.

In some implementations, as shown in FIG. 7D, portions of the protection layer 787 can be removed to expose the top surfaces of the ends of the semiconductor bodies 732. In some implementations, the portions of the protection layer 787 above the top surfaces of the ends of the semiconductor bodies 732 can be removed by using any suitable method, such as a CMP process. As such, the top surfaces of the ends of the semiconductor bodies 732 and the protection layer 787 can be coplanar.

Referring back to FIG. 6, method 600 can proceed to operation 606, in which SNC structures can be formed on the source ends of the semiconductor bodies of the vertical transistors. FIGS. 7E-7H illustrate schematic side cross-sectional views of the semiconductor structure in the y-z plane at various stages of operation 606 of method 600.

In some implementations, as shown in FIG. 7E, portions of the ends of the semiconductor bodies 732 can be removed to form second recesses 786. In some implementations, the second recesses 786 can be formed by using any suitable etching processes (e.g., dry etching, wet etching, etc.) and cleaning processes (e.g., SC1) to remove portions of the ends of the semiconductor bodies 732. In some implementations, the exposed ends of the semiconductor bodies 732 can be doped with N-type dopants (e.g., P or As) or P-type dopants (e.g., B or Ga) at a desired doping level by using any suitable ion implantation process to form sources of the vertical transistors 711.

In some implementations, as shown in FIG. 7F, a silicide layer 781 can be formed on the source ends of the semiconductor bodies 732 of the vertical transistors 711. In some implementations, the silicide layer 781 can be formed by any suitable process, such as RTA processes. For example, a thin layer of metal (e.g., Ti, Co, or Ni) can be deposited on the source ends of the semiconductor bodies 732 of the vertical transistors 711 using methods such as sputtering or CVD. A first low-temperature RTA process (also referred to as an initial RTA or a pre-RTA) may be performed to form an intermediate phase of silicide (e.g., TiSi for titanium silicide, NiSi for nickel silicide, CoSi for cobalt silicide). A cleaning process can then be performed to remove extra metal materials. Next, a second high-temperature RTA process can be performed to complete the formation of the silicide layer 781 and activate the dopants of the source ends of the semiconductor bodies 732 of the vertical transistors 711.

In some implementations, as shown in FIG. 7G, a conductive layer 783 can be formed to cover the silicide layer 781 and protection layer 787. In some implementations, the conductive layer 783 can be a polysilicon layer or a metal layer formed by any suitable thin film deposition process (e.g., CVD, PVD, ALD, etc.). In some implementations, as shown in FIG. 7H, portions of the conductive layer 783 can be removed by any suitable process (e.g., wet etching, dry etching, CMP, etc.), such that the top surface of the conductive layer 783 is lower than the top surface of the protection layer 787. The silicide layer 781 and the conductive layer 783 in each second recess 786 can constitute an SNC structure 780.

Referring back to FIG. 6, method 600 can proceed to operation 608, in which a storage layer can be formed on the SNC structures and the protection layer. FIG. 7I illustrates a schematic side cross-sectional view of the semiconductor structure in the y-z plane after operation 608 of method 600.

As shown in FIG. 7I, forming the first semiconductor stack can further comprise forming a storage layer 720 vertically stacked on the SNC structures 780 and the protection layer 787. In some implementations, forming storage layer 720 comprises forming an array of capacitors 721 each coupled with a corresponding one of the array of vertical transistors 711. In some implementations, forming the array of capacitors 721 comprises forming a first electrode 752, forming a second electrode 754, and forming a dielectric layer 756 formed between first electrode 752 and second electrode 754 by any suitable thin film deposition processes (e.g., CVD, PVD, ALD, etc.).

In some implementations, a mesh structure 746 can be formed in a sacrificial layer (not shown), and a plurality of through holes (not shown) can be formed in the sacrificial layer. The first electrode 752 can be formed by depositing one or more layers of conductive materials including, but not limited to, W, Co, Cu, Al, TiN, TaN, polysilicon, silicide, or any combination thereof, to form a hollow cylinder shape structure in the through holes and being fixed in a mesh structure 746. Each first electrode 752 can be in contact with the conductive layer 783 of a corresponding one of the array of SNC structures 780. In some implementations, forming the first electrode 752 can include forming a polysilicon layer 752-1 and a TiN layer 752-2, as shown in FIG. 7I. The dielectric layer 756 can be formed by depositing a high-k material (e.g., Al₂O₃, HfO₂, Ta₂O₅, ZrO₂, TiO₂) to cover the first electrode 752. The sacrificial layer can then be removed, and the second electrodes 754 can be formed on the dielectric layer 756. In some implementations, the second electrodes 754 can be formed by depositing one or more layers of conductive materials including, but not limited to, W, Co, Cu, Al, TiN, TaN, polysilicon, silicide, or any combination thereof. In some implementations, forming the second electrode 752 can include forming a GeSi layer 754-1 and a TiN layer 754-2. In some implementations, forming the storage layer 720 further comprises forming a lateral conductive layer coupled with the array of second electrodes 754 to form a common second electrode of the array of capacitors 721.

It is noted that, method 600 can further include any other suitable operations that are not shown in FIG. 6. For example, as shown in FIG. 7J, method 600 can further include forming a carrier substrate 759 on the storage layer 720, flipping the formed structure, removing the semiconductor layer 731, portions of the insulating layer 739, and portions of the gate electrode 736. In some implementations, the TISO can be partially removed to form one or more air gaps 723. Portions of the insulating layer 739 and the semiconductor layer 731 can then be reformed to cover the gate electrode 736. In some implementations, semiconductor layer 731 can be doped with N-type dopants (e.g., P or As) or P-type dopants (e.g., B or Ga) at a desired doping level to form a common drain of a column of vertical transistors 711. In some implementations, method 600 can further include forming bit lines coupled with semiconductor layer 731. In some implementations, method 600 can further include forming one or more interconnection layers.

Accordingly, DRAM memory devices including self-aligned SNC structures and the fabricating methods thereof are provided in the present disclosure. The disclosed memory devices and fabricating methods provide benefits for silicide interface treatment and protection, reduce silicon damage, increase stability of source end ion implantation and silicide overlap, prevent WL/TISO missing, and provide accurate expansion of holes for forming the SNC structure.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations but should be defined only in accordance with the following claims and their equivalents.

What is claimed is:

1. A memory device, comprising:
an array of transistors each comprising a semiconductor body extending along a vertical direction, wherein gate structures of adjacent transistors are laterally separated from each other by an insulating layer having a first material;
an array of contact structures each aligned with a corresponding semiconductor body in the vertical direction, wherein adjacent contact structures are laterally separated from each other by a protection layer having a second material different from the first material; and
an array of capacitors each in contact with a corresponding one of the array of contact structures.

2. The memory device of claim 1, wherein each contact structure comprising:
a silicide layer in contact with a doped end of the corresponding semiconductor body; and
a conductive layer in contact with a first electrode of a corresponding one of the array of capacitors.

3. The memory device of claim 2, wherein:
a vertical distance between the silicide layer of each contact structure and the gate structure of the corresponding transistor is in a range from about 40 nm to about 70 nm.

4. The memory device of claim 1, wherein:
the first material comprises silicon oxide; and
the second material comprises silicon nitride.

5. The memory device of claim 2, wherein:
the insulating layer extends in between the silicide layer and the protection layer; and
a first lateral dimension of the silicide layer is less than a second lateral dimension of the conductive layer.

6. The memory device of claim 2, wherein a sidewall of the silicide layer of each contact structure is vertically aligned with a sidewall of the corresponding semiconductor body.

7. The memory device of claim 2, wherein each semiconductor body has a cylinder shape without an enlarged end adjacent to the silicide layer.

8. A memory device, comprising:
an array of transistors each comprising a semiconductor body extending along a vertical direction and a gate structure at a lateral side of the semiconductor body;
an array of contact structures each aligned with a corresponding one of the semiconductor bodies of the array of transistors in the vertical direction, wherein vertical distances between the contact structures and the gate structures are in a range from about 40 nm to about 70 nm;
a protection layer located between adjacent contact structures to separate the array of contact structures from each other; and
an array of capacitors each in contact with a corresponding one of the array of contact structures.

9. The memory device of claim 8, wherein each contact structure comprising:
a silicide layer in contact with a doped end of the corresponding semiconductor body; and
a conductive layer in contact with a first electrode of a corresponding one of the array of capacitors.

10. The memory device of claim 9, wherein:
the gate structures of adjacent transistors are laterally separated from each other by an insulating layer having a first material different from a second material of the protection layer.

11. The memory device of claim 10, wherein:
the first material comprises silicon oxide; and
the second material comprises silicon nitride.

12. The memory device of claim 10, wherein:
the insulating layer extends in between the silicide layer and the protection layer; and
a first lateral dimension of the silicide layer is less than a second lateral dimension of the conductive layer.

13. The memory device of claim 9, wherein a sidewall of the silicide layer of each contact structure is vertically aligned with a sidewall of the corresponding semiconductor body.

14. The memory device of claim 9, wherein each semiconductor body has a cylinder shape without an enlarged end adjacent to the silicide layer.

15. A method of forming a memory device, comprising:
forming an array of transistors each comprising a semiconductor body extending along a vertical direction, wherein gate structures of adjacent transistors are laterally separated from each other by an insulating layer having a first material;
forming an array of contact structures each aligned with a corresponding semiconductor body in the vertical direction, wherein adjacent contact structures are laterally separated from each other by a protection layer having a second material different from the first material; and
forming an array of capacitors each in contact with a corresponding one of the array of contact structures.

16. The method of claim 15, wherein forming the array of contact structures comprises:
forming the protection layer covering ends of the semiconductor bodies and between ends of the semiconductor bodies of the array of transistors;
removing portions of the protection layer to expose the ends of the semiconductor bodies; and
removing portions of the ends of the semiconductor bodies to form recesses.

17. The method of claim 16, further comprising:
before forming the protection layer, removing portions of the insulating layer to expose sidewalls of the ends of the semiconductor bodies; and
forming a spacer layer covering top surfaces and the sidewalls of the ends of the semiconductor bodies.

18. The method of claim 16, wherein forming the array of contact structures further comprises:
doping the ends of the semiconductor bodies from the recesses;
forming a silicide layer on doped ends of the semiconductor bodies; and
forming a conductive layer on the silicide layer.

19. The method of claim 18, wherein forming the silicide layer comprises:
depositing a metal material in the recesses;
performing a first rapid heat annealing process to diffuse the metal material into the doped ends of the semiconductor bodies;
removing exceeded metal material; and
performing a second rapid heat annealing process to form the silicide layer.

20. The method of claim 18, wherein forming the array of capacitors comprises:
forming first electrodes of the array of capacitors, wherein each first electrode is in contact with the conductive layer of a corresponding one of the array of contact structures;
forming a high-k layer covering the first electrodes;
forming second electrodes of the array of capacitors on the high-k layer; and
forming a common electrode in contact with the second electrodes.
